(19) United States
(12) Patent Application Publication
(10) Pub. No.: US 2004/0053506 A1
(43) Pub. Date: Mar. 18, 2004

(54) High temperature anisotropic etching of multi-layer structures

(76) Inventor: Yao-Sheng Lee, Tampa, FL (US)

Correspondence Address: Harvey S. Kauget, Holland & Knight LLP, Suite 4100, 100 N. Tampa Street, Tampa, FL, 33602-3644, US

(21) Appl. No.: 10/616,492

(22) Filed: Jul. 8, 2003

Related U.S. Application Data
(60) Provisional application No. 60/397,185, filed on Jul. 19, 2002.

(51) Int. Cl. H01L 21/461; C23F 1/00

(52) U.S. Cl. 438/718; 438/725; 156/345.48

(57) ABSTRACT

An alternative etching chemistry which can provide inherently anisotropic etching and eliminate notch formation without the need for heavy polymer deposition is provided by the present invention. The etch is performed with a combination of HBr and N₂ at substrate temperatures greater than approximately 160° C. to provide an essentially notch-free and carbon-polymer free anisotropic etching process. The alternative etching chemistry allows for the production of substantially vertical features with smooth sidewalls in an Indium containing multiple layered structure in an ICP plasma etch system.

### CROSS REFERENCES TO RELATED APPLICATIONS

This application claims priority from and is related to commonly owned U.S. Provisional Patent Application Serial No. 60/397,185, filed Jul. 19, 2002, entitled: HIGH TEMPERATURE ANISOTROPIC ETCHING OF MULTI-LAYER STRUCTURES, this Provisional Patent Application incorporated by reference herein.

### FIELD OF THE INVENTION

The present invention relates generally to the field of semiconductor manufacturing. More particularly, the present invention relates to the use of a combination of HBr and N₂ at relatively high substrate temperatures to provide an essentially notch-free and clean anisotropic etching process for Indium containing materials in a plasma etch system.

### BACKGROUND OF THE INVENTION

Indium containing multi-layer structures (InP, InGaAs and InGaAsP) are becoming more important in the fabrication of optoelectronic devices, which include vertical-cavity surface-emitting lasers and ridge waveguides. Most methods for dry etching Indium containing materials involve the use of methane/hydrogen mixtures (CH₄/H₂) and chlorine based plasmas. Although CH₄/H₂-based plasmas have been widely used to etch InP, the etch rate is slow and polymer deposition causes contamination of the etcher and the etched samples. The slow etch rate and the unstable etching conditions are not acceptable for high-volume manufacturing. Chlorine-based chemistries have been reported to etch InP with a smooth surface and high etch rate at substrate temperatures around 200° C.

However, we have discovered that Chlorine-based chemistries (Cl₂, BCl₃) will produce a notch in multi-layer structures due to the different etch rates for these materials. We have found that this notch formation will preclude subsequent process steps, such as re-growth. Bromine-based chemistries, such as HBr and Br₂, have also been reported to etch InP, but HBr or HBr/Ar plasmas usually result in a severe undercut, which is unacceptable for further processing.

A vertical etch is a major requirement for these applications, and so additional gases have been added to the plasma to improve the passivation of the sidewall and eliminate the undercut. The most common method is to use hydrocarbons, such as CH₄, to form a hydrocarbon polymer on the sidewall to prevent the undercut. Although the polymer formation helps to reduce the undercut, we have found that the polymer formed on the sidewall will lead to the failure of re-growth. Hence, it is necessary to remove the polymer after etching. Typically, this polymer is removed either in situ using an oxygen plasma or commercial stripper. However, this extra processing step adds to the cost of the process. Thus, it would be very advantageous to reduce or eliminate the need for any post-etch clean-up processing. In addition, the heavy polymer deposits formed in the chamber during the etch will result in a gradual process shift after several cycles of the process.

Nitrogen (N₂) has been reported as an additive to gas mixtures to improve the verticality of the etched profile. Previous work by Satoshi et. al. discloses the use of Br₂/N₂ chemistries in a reactive ion beam configuration in the following process space:

| | |
|---|---|
| N₂ | 0.23 mtorr |
| Br₂ | 0-0.1 mtorr |
| Temperature | 40-200° C. |

In order to achieve smooth vertical sidewalls, the Satoshi process was limited to Br₂ pressures of 0.04 mtorr or less and temperatures greater than 100° C.

Thomas et. al disclosed a Cl₂/Ar/N₂ based process for InP etching in an inductively coupled plasma (ICP) system. This process operated at the elevated temperature of 180° C. and resulted in etch rates of 1.6 μm/minute with vertical feature sidewalls for an InGaAs/InP/InGaAsP epitaxial stack.

Chino et. al (U.S. Pat. Nos. 5,968,845 and 6,127,201) disclose the use of a halogen/N₂ gas mixture to anisotropically etch InP with a smooth etched surface at a temperature in the range 100° C.-200° C.

Lishan et. al (proceedings, GaAs MANTECH, 2001) have disclosed Hydrogen/Bromide (HBr, HBr/Ar, HBr/He) based processes for etching InP over a range of temperatures (25°-160° C.). The room temperature processes resulted in slower InP etch rates (<2000 Å/minute) and sloped feature profiles. Etching at elevated temperatures resulted in higher etch rates (˜1 μm/minute) and undercut feature profiles suitable for downstream lift-off metallization processes.

### SUMMARY OF THE INVENTION

A preferred embodiment of the present invention is directed toward a process for the anisotropic dry etching of a compound semiconductor heterostructure containing Indium. Most preferably, the semiconductor heterostructure includes at least one of InP, InGaAs and InGaAsP. In accordance with the process, a surface of the heterostructure is selectively masked. The masked heterostructure is then exposed to a plasma comprising a mixture of hydrogen bromide and nitrogen to anisotropically etch the unmasked portion of the heterostructure in a direction generally perpendicular to the major surface, and without causing notching at the layer interfaces. The etching is preferably performed with an inductively coupled plasma etching system at a rate of at least 2 μm/minute and a pressure of approximately 5 mtorr. Other plasma techniques, such as RIE, ECR or Helicon may similarly be used. The semiconductor heterostructure is maintained at a temperature above 160° C.

Another embodiment of the invention is directed toward a method of etching a substantially vertical feature in a semiconductor substrate in a etching chamber. The temperature of the semiconductor substrate in the etching chamber is maintained above approximately 160° C. A mask is deposited on the semiconductor substrate. The semiconductor substrate is then etched with a mixture of hydrogen bromide and nitrogen.

Yet another embodiment of the present invention is directed toward a device for etching a feature in a semiconductor substrate containing at least some Indium wherein the feature is substantially perpendicular to the surface of the semiconductor substrate. The device includes a heater for maintaining the temperature of the semiconductor substrate at a temperature above approximately 160° C. A gas supply provides a mixture of hydrogen bromide and nitrogen for use in etching the semiconductor substrate. An inductively coupled plasma source etches the semiconductor substrate at a rate of at least 2 μm/minute while a pressure regulator maintains a pressure of approximately 5 mtorr during the etching of the semiconductor substrate.

The above described methods and apparatus are advantageous in that they produce substantially vertical features in a semiconductor substrate that have smooth side walls. In particular, there is no evidence of notching at the interface between the different layers. The smooth features are created without significantly compromising the etch rate of the process and without requiring time consuming and inefficient additional process steps. Therefore, the present invention represents a substantial improvement upon the prior art.

### BRIEF DESCRIPTION OF THE DRAWINGS

FIGS. 1(a-c) are diagrams of indium containing substrates suitable for etching in accordance with preferred embodiments of the present invention;

FIG. 2 is a SEM of a notch that resulted from etching the substrate of FIG. 1(a) with HBr/BCl₃/CH₄/Ar in an ICP plasma;

FIG. 3 is a SEM of a minimized notch after the elimination of BCl₃ from the gas mixture utilized to produce the notch of FIG. 2;

FIG. 4 shows the severe undercut that results when HBr/Ar plasma is used to etch the structure of FIG. 1(b);

FIG. 5 demonstrates the use of HBr/N₂ for ICP plasma etching of the structure of FIG. 1(b) with a substrate temperature of approximately 160° C.;

FIG. 6 shows the results of the use of HBr/N₂ in an ICP plasma etch applied to the structure of FIG. 1(c); and

FIG. 7 further demonstrates the results of the use of HBr/N₂ in an ICP plasma etch applied to the structure of FIG. 1(c).

### DETAILED DESCRIPTION OF THE INVENTION

The present invention is directed toward an alternative etching chemistry which can provide inherently anisotropic etching and eliminate notch formation without the need for heavy polymer deposition. More particularly, preferred embodiments of the present invention are directed toward using a combination of HBr and N₂ at substrate temperatures greater than 160° C. to provide an essentially notch-free and carbon-polymer free anisotropic etching process for Indium containing materials in an ICP plasma etch system.

In accordance with one preferred embodiment of the present invention, a method for high density (ICP) plasma etching of Indium containing multi-layer structures using Hydrogen Bromide with the addition of Nitrogen to protect the sidewall and inhibit undercutting during the etch is disclosed. The etching is preferably conducted at a substrate temperature greater than approximately 160° C. Etching under these conditions provides a clean, notch-free structure. Further, when etching Indium containing multi-layer structures, etch rates of at least 2 μm/minute are achieved. The selectivity of the process with respect to a SiNₓ or SiO₂ mask is typically larger than 20:1.

The center-point process for the HBr/N₂ chemistry is preferably

| | |
|---|---|
| HBr | 60 sccm |
| N₂ | 9 sccm |
| Pressure | 5 mtorr |
| RF Bias | 100 W |
| ICP Power | 600 W |
| Temperature | 160° C. |

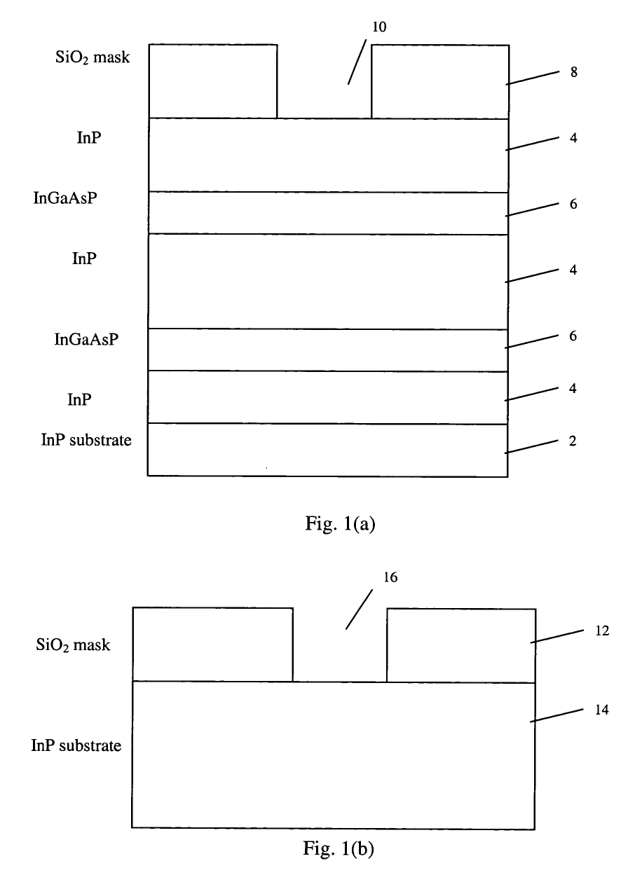

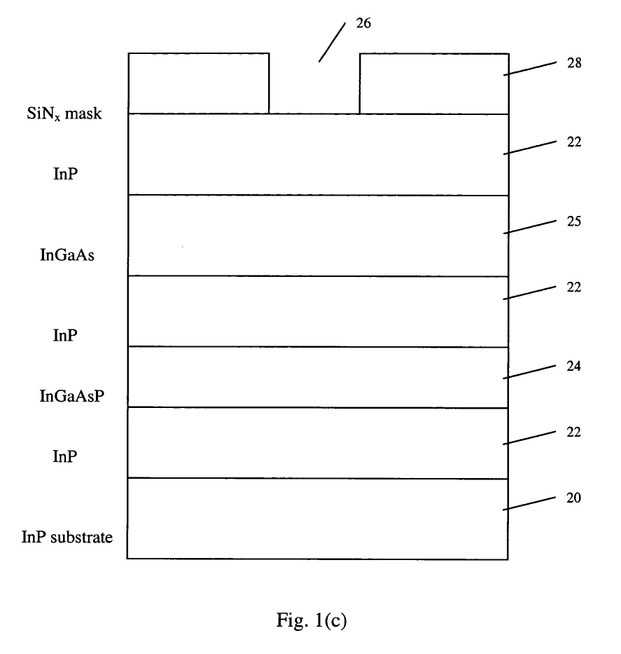

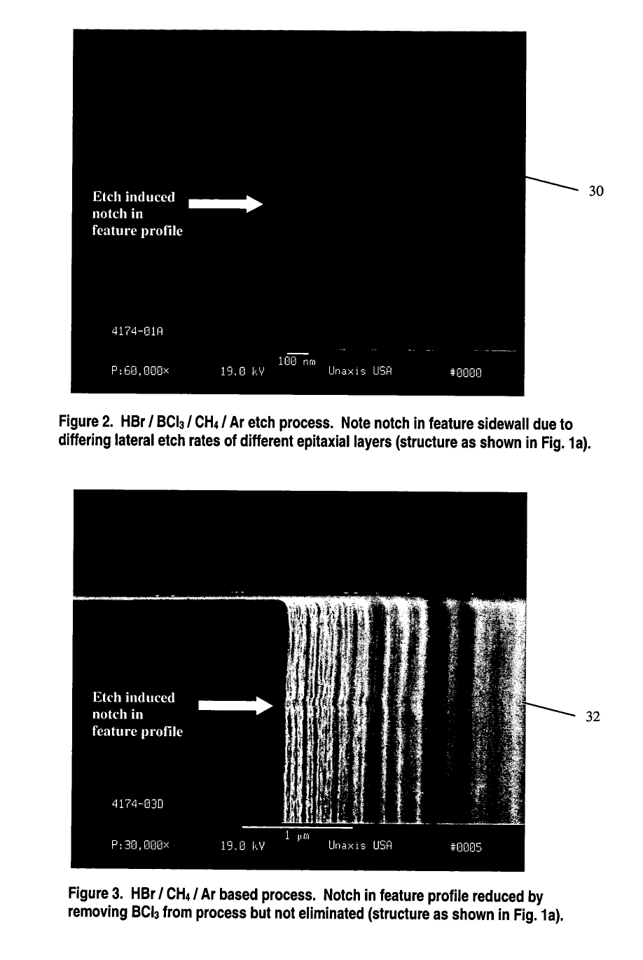

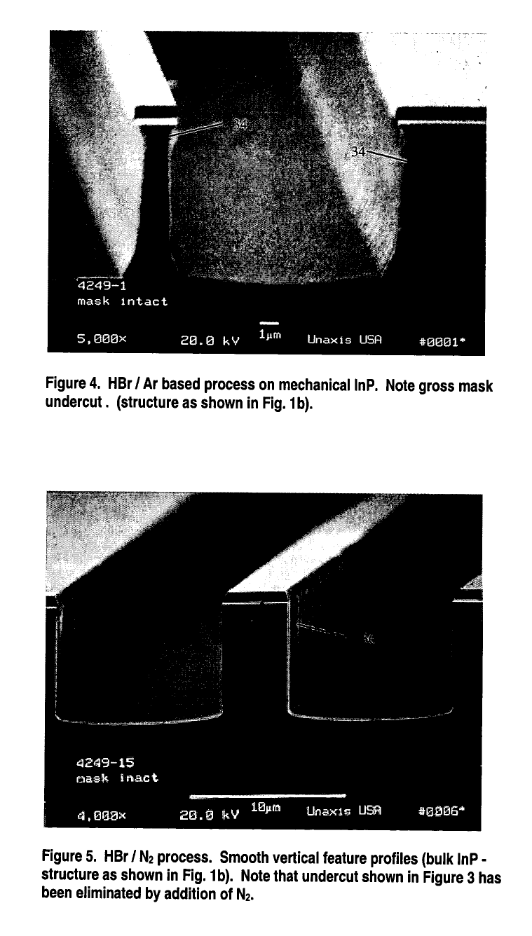

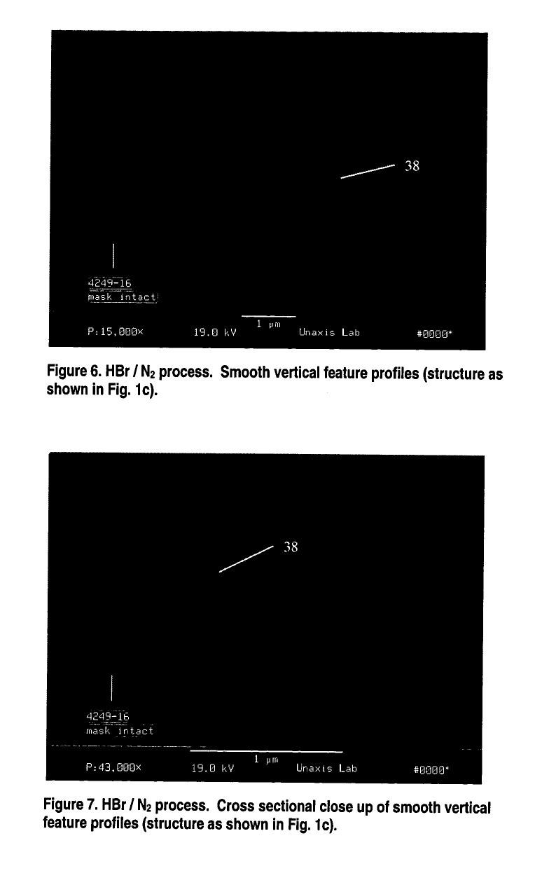

As set forth in more detail below and in FIGS. 1(a-c), three types of patterned wafers were used to demonstrate the utility of the preferred embodiments of the present invention. FIG. 1(a) depicts a layered wafer consisting of a InP substrate layer 2 having alternating layers of InP 4 and InGaAsP 6 deposited thereon. A SiO₂ mask 8 covers the top InP layer 4. The mask 8 has an opening 10 that allows the InP 4 and InGaAsP 6 layers to be etched. FIG. 1(b) depicts a SiO₂ mask 12 deposited directly on an InP substrate 14 with a pattern hole 16 for etching. FIG. 1(c) depicts a layered wafer consisting of an InP substrate layer 20 having multiple layers of InP 22 and interspersed layers of InGaAsP 24 and InGaAs 25 deposited thereon. A patterned hole 26 in a SiNₓ mask 28 is provided for etching.

The patterned Indium containing multi-layer InP and InGaAsP structure shown in FIG. 1(a) was etched with HBr/BCl₃/CH₄/Ar in an ICP plasma. A significant notch 30 was observed after the etch as shown in FIG. 2. With the elimination of BCl₃ from the gas mixture, the notch 32 was substantially reduced as shown in FIG. 3. This reduction in notching is significant in that it allows for subsequent process steps, such as re-growth, to be performed on the substrate. However, there is difficulty in subsequent re-growth processing steps without a post-treatment processing step due to the hydrocarbon polymer deposited on the sidewall. The use of additional post-treatment processing steps is undesirable in that it increases the overall costs of the manufacturing process.

Elimination of the carbon polymer-forming component (CH₄) from the gas mixture results in a severe undercut 34 of the mask when HBr/Ar plasma is applied to etch the structure of FIG. 1(b) as shown in FIG. 4.

FIG. 5 demonstrates the use of HBr/N₂ for ICP plasma etching of the bulk InP structure of FIG. 1(b) with a substrate temperature of 160° C. A vertical and smooth etched surface 36 is observed. When HBr/N₂ in an ICP plasma was applied to the structure of FIG. 1(c) which has Indium containing multi-layers InP layers 22, InGaAs layer 25 and InGaAsP layer 24, a highly vertical, notch-free, smooth and clean surface 38 was obtained as shown in FIGS. 6 and 7.

The production of a vertical, notch-free, smooth and clean surface during an etching process is obviously beneficial in a variety of ways that will be readily discernible to those skilled in the art. The fabrication of optoelectronic devices including vertical-cavity surface-emitting lasers and ridge waveguides are merely exemplary processes to which the present invention can be advantageously applied.

It will be understood that the specific embodiments of the invention shown and described herein are exemplary only. Numerous variations, changes, substitutions and equivalents will now occur to those skilled in the art without departing from the spirit and scope of the present invention. Accordingly, it is intended that all subject matter described herein and shown in the accompanying drawings be regarded as illustrative only and not in a limiting sense and that the scope of the invention be solely determined by the appended claims.

I claim:

1. A process for anisotropically dry etching a compound semiconductor heterostructure, said process comprising:
selectively masking a surface of the heterostructure; and
exposing the masked heterostructure to a plasma comprising a mixture of hydrogen bromide and nitrogen to anisotropically etch the unmasked portion of the heterostructure in a direction generally perpendicular to the major surface.

2. The process of claim 1 further comprising maintaining the semiconductor heterostructure at a temperature above 160° C.

3. The process of claim 1 wherein the semiconductor heterostructure contains Indium.

4. The process of claim 1 wherein the semiconductor heterostructure includes at least one of InP, InGaAs and InGaAsP.

5. The process of claim 1 further comprising the step of performing the process with an inductively coupled plasma etching system.

6. The process of claim 1 wherein the etching is performed at a rate of at least 2 μm/minute.

7. The process in claim 1 further comprising the step of maintaining a pressure of approximately 5 mtorr during etching of the heterostructure.

8. A method of etching a substantially vertical feature in a semiconductor substrate in a vacuum chamber, said method comprising:
depositing a mask on the semiconductor substrate;
maintaining the temperature of the semiconductor substrate in the vacuum chamber above approximately 160°C.; and
etching the semiconductor substrate with a mixture of hydrogen bromide and nitrogen.

9. The method of claim 8 wherein the semiconductor substrate further comprises Indium.

10. The method of claim 8 wherein the semiconductor substrate further comprises at least one of InP, InGaAs and InGaAsP.

11. The method of claim 8 further comprising the step of performing the etching step with a high density plasma source.

12. The method of claim 11 further comprising the step of performing the etching step with an inductively coupled plasma source.

13. The method of claim 8 wherein the etching is performed at a rate of at least 2 μm/minute.

14. The method of claim 8 further comprising the step of maintaining a pressure in the vacuum chamber of approximately 5 mtorr.

15. A device for etching a feature in a semiconductor substrate wherein said feature is substantially perpendicular to the surface of the semiconductor substrate, said device comprising
a heater for maintaining the temperature of the semiconductor substrate at a temperature above approximately 160° C.; and
a gas supply for providing a mixture of hydrogen bromide and nitrogen for use in etching the semiconductor substrate.

16. The device of claim 15 further comprising an inductively coupled plasma source.

17. The device of claim 15 wherein the semiconductor substrate contains at least some Indium.

18. The device of claim 15 wherein the semiconductor substrate further comprises at least one of InP, InGaAs and InGaAsP.

19. The device of claim 15 further comprising etching means for etching the semiconductor substrate at a rate of at least 2 μm/minute.

20. The device of claim 15 further comprising a pressure regulator for maintaining a pressure of approximately 5 mtorr during the etching of the semiconductor substrate.
